(19) United States
(12) Patent Application Publication
(10) Pub. No.: US 2018/0045903 A1
(43) Pub. Date: Feb. 15, 2018

(54) OPTICAL-ELECTRIC CIRCUIT BOARD

(71) Applicant: OLYMPUS CORPORATION, Tokyo (JP)

(72) Inventor: Yusuke NAKAGAWA, Kamiina-gun (JP)

(73) Assignee: OLYMPUS CORPORATION, Tokyo (JP)

(21) Appl. No.: 15/726,475

(22) Filed: Oct. 6, 2017

Related U.S. Application Data
(63) Continuation of application No. PCT/JP2015/060827, filed on Apr. 7, 2015.

(51) Int. Cl. G02B 6/42; H05K 1/14; H05K 1/02; H05K 1/18; G02B 6/122; G02B 6/036

(52) U.S. Cl. CPC G02B 6/428; G02B 6/122; G02B 6/4214; G02B 6/03616; H05K 1/0274; H05K 1/181; H05K 1/144; G02B 2006/12069

(57) ABSTRACT

An optical-electric circuit board includes: a polymer-type optical waveguide substrate provided with a reflective surface which optically couples a first optical path and a second optical path to each other; and electrical wiring, wherein at least a portion of a member which configures the reflective surface is formed of a conductive member, the electrical wiring is formed of first wiring disposed on a side of a first principal surface of the optical waveguide substrate and second wiring disposed on a side of a second principal surface of the optical waveguide substrate, and the conductive member electrically connects the first wiring and the second wiring with each other.

### CROSS REFERENCE TO RELATED APPLICATION

This application is a continuation application of PCT/JP2015/060827 filed on Apr. 7, 2015, the entire contents of which are incorporated herein by this reference.

### BACKGROUND OF THE INVENTION

### 1. Field of the Invention

The present invention relates to an optical-electric circuit board which includes a polymer-type optical waveguide substrate provided with a reflective surface which optically couples a first optical path and a second optical path to each other.

### 2. Description of the Related Art

An optical waveguide substrate having an optical waveguide allows an optical circuit to be miniaturized. To drive an optical element such as a light emitting element which optically couples to an optical path of the optical waveguide and to transmit a signal of the optical element, it is necessary to provide electrical wiring. Accordingly, an optical-electric circuit board has been developed where an optical waveguide substrate having an optical circuit and a wiring board having an electric circuit are formed into an integral body.

Japanese Patent Application Laid-Open Publication No. 2013-68650 discloses an optical-electric circuit board where an optical element is arranged on an upper surface of the optical-electric circuit board. An optical waveguide substrate is arranged on a center portion of the optical-electric circuit board. Conducting members are arranged on an outer peripheral portion of the optical-electric circuit board, and each conducting member has through wiring which extends from the upper surface to a lower surface of the optical-electric circuit board. That is, in the optical-electric circuit board, the optical waveguide substrate forming an optical circuit board and the conducting member forming an electric circuit board are disposed individually and separately.

### SUMMARY OF THE INVENTION

An optical-electric circuit board according to an embodiment of the present invention is an optical-electric circuit board which includes: a polymer-type optical waveguide substrate provided with a reflective surface which optically couples a first optical path and a second optical path to each other; and electrical wiring, wherein at least a portion of a member which configures the reflective surface is formed of a conductive member, the electrical wiring is formed of first wiring disposed on a side of a first principal surface of the optical waveguide substrate and second wiring disposed on a side of a second principal surface of the optical waveguide substrate, and the conductive member electrically connects the first wiring and the second wiring with each other.

### BRIEF DESCRIPTION OF THE DRAWINGS

FIG. 1 is a cross-sectional view of an optical-electric circuit board according to a first embodiment;

FIG. 2 is an exposed view of the optical-electric circuit board according to the first embodiment;

FIG. 3 is a cross-sectional view of an optical-electric circuit board according to a modification of the first embodiment;

FIG. 4A is a top plan view of an optical-electric circuit board according to a second embodiment;

FIG. 4B is a cross-sectional view of the optical-electric circuit board according to the second embodiment;

FIG. 5A is a perspective view of a micro pin of the optical-electric circuit board according to the second embodiment;

FIG. 5B is a perspective view of a micro pin of an optical-electric circuit board according to a modification of the second embodiment;

FIG. 5C is a perspective view of a micro pin of the optical-electric circuit board according to a modification of the second embodiment;

FIG. 5D is a perspective view of a micro pin of the optical-electric circuit board according to a modification of the second embodiment;

FIG. 5E is a perspective view of a micro pin of the optical-electric circuit board according to a modification of the second embodiment;

FIG. 5F is a perspective view of a micro pin of the optical-electric circuit board according to a modification of the second embodiment;

FIG. 5G is a perspective view of a micro pin of the optical-electric circuit board according to a modification of the second embodiment;

FIG. 6 is an exposed view of an optical-electric circuit board according to a third embodiment; and

FIG. 7 is an exposed view of an optical-electric circuit board according to a modification of the third embodiment.

### DETAILED DESCRIPTION OF THE PREFERRED EMBODIMENT(S)

### First Embodiment

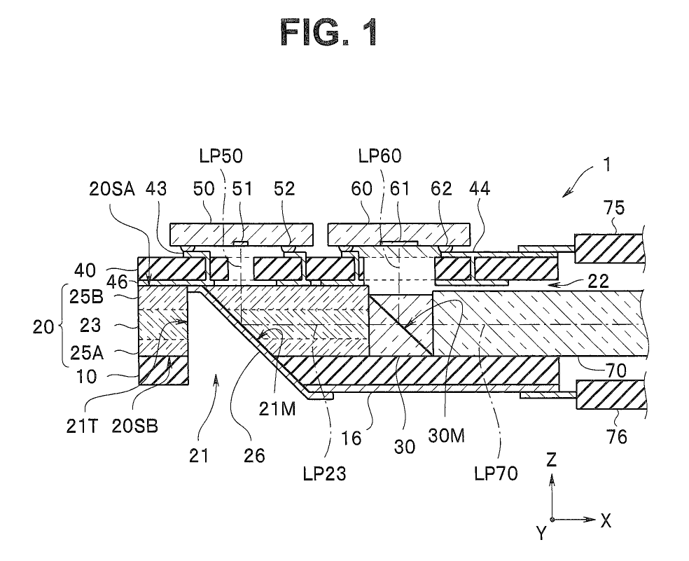

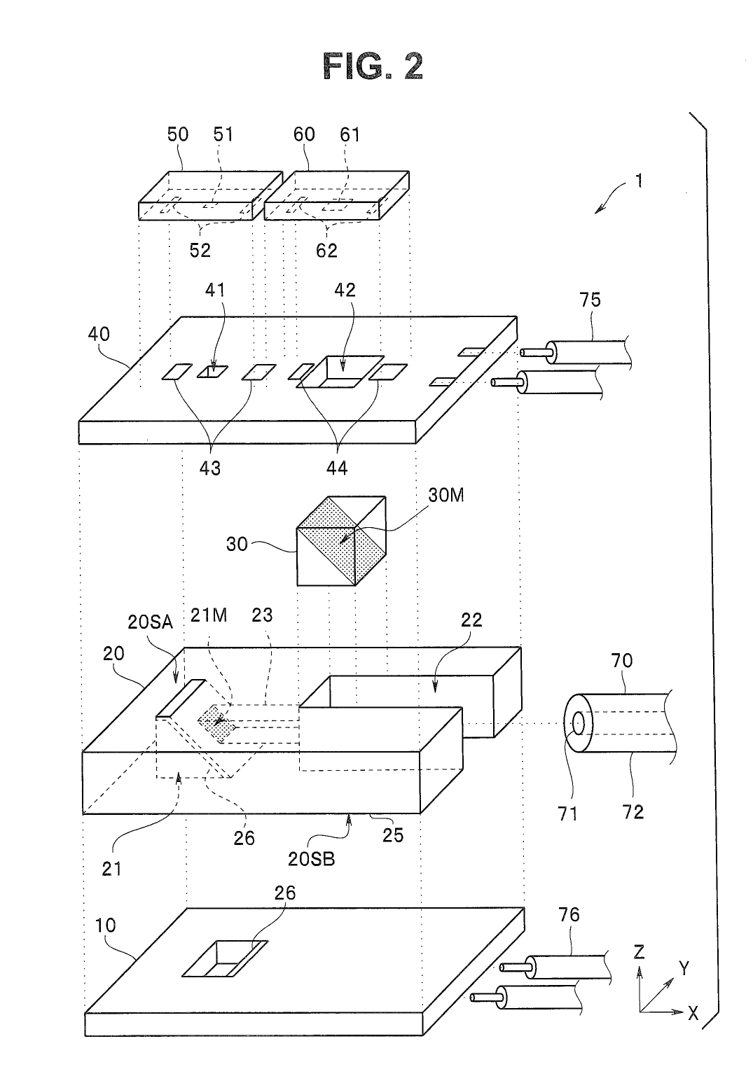

As shown in FIG. 1 and FIG. 2, an optical-electric circuit board 1 according to a first embodiment of the present invention includes a polymer-type optical waveguide substrate 20 as a main constitutional element, and also includes a first wiring board 10 and a second wiring board 40.

Here, in the description made hereinafter, drawings referenced in respective embodiments are schematic. Note that a relationship between a thickness and a width of respective parts, and a thickness ratio, a relative angle and the like of each part differ from those of an actual optical-electric circuit board. Some parts may have a different size relationship or a different size ratio between drawings.

The optical-electric circuit board 1 includes: a light emitting element 50 forming a first optical element; a light receiving element 60 forming a second optical element; the optical waveguide substrate 20; an optical fiber 70; and signal cables 75, 76. The second board (the second wiring board) 40 on which the light emitting element 50 and the light receiving element 60 are mounted is disposed on an upper surface 20SA forming a first principal surface of the optical waveguide substrate 20.

The first board (the first wiring board) 10 is disposed on a lower surface 20SB forming a second principal surface of the optical waveguide substrate 20.

In the optical-electric circuit board 1, the light emitting element 50 transmits a first optical signal with first wavelength λ1 the light receiving element 60 receives a second optical signal with second wavelength λ2 which differs from the first wavelength λ1, and a third optical signal which is formed by multiplexing the first optical signal and the second optical signal is guided by the optical fiber 70. For example, the first wavelength λ1 is 850 nm, and the second wavelength λ2 is 650 nm.

The light emitting element 50 is formed of a vertical cavity surface emitting laser (VCSEL). The light emitting element 50 emits light of an optical signal to a light emitting surface (XY plane) in the vertical direction (Z axis direction) in response to a drive electrical signal inputted to the light emitting element 50. For example, the highly miniaturized light emitting element 50 with a size of 250 μm×300 μm as viewed in a plan view has, on the light emitting surface thereof: a light emitting portion 51 having a diameter of 20 μm; and connection terminals 52 which are electrically connected to the light emitting portion 51 so as to supply an electrical signal.

The light receiving element 60 is formed of a photodiode (PD) or the like. The light receiving element 60 converts an optical signal which is incident on a light receiving surface from the vertical direction (Z axis direction) into an electrical signal, and the light receiving element 60 outputs the electrical signal. For example, the highly miniaturized light receiving element 60 with a size of 250 μm×300 μm as viewed in a plan view has, on the light receiving surface thereof: a light receiving portion 61 having a diameter of 50 μm; and connection terminals 62 which are electrically connected with the light receiving portion 61 so as to output the received electrical signal.

The optical waveguide substrate 20 is a polymer-type optical waveguide substrate where the longitudinal direction of a core 23 extends in the X axis direction, and a periphery of the core 23 is surrounded by a cladding 25. The core 23 which guides an optical signal configures an optical path LP23. The polymer-type optical waveguide substrate 20 where the core 23 and the cladding 25 are made of a resin can be easily processed and has sufficiently high plasticity compared to an optical waveguide substrate made of an inorganic material such as quartz. Further, the optical-electric circuit board 1 is formed by sandwiching the optical waveguide substrate 20 having flexibility between the two flexible first board 10 and second board 40 so that the optical-electric circuit board 1 has flexibility and hence, the optical-electric circuit board 1 can be easily disposed in a narrow space. That is, it is preferable that the first board 40 and the second board 10 have flexibility.

The core 23 forming the optical waveguide is made of a first resin, and the cladding 25 is made of a second resin having a smaller refractive index than the first resin. As described later, the cladding 25 is formed of a lower cladding 25A disposed below the core 23 and an upper cladding 25B surrounding side surfaces and an upper surface of the core 23.

To efficiently transmit light, a difference in refractive index between the core 23 and the cladding 25 is preferably set to 0.01 or more. The core 23 configures the optical waveguide which is an optical path for guiding an optical signal.

For example, the core 23 and the cladding 25 are made of a fluorinated polyimide resin. The fluorinated polyimide resin has sufficiently high heat resistance, transparency and isotropy, and a refractive index of the fluorinated polyimide resin is 1.50 to 1.60.

The light emitting element 50 and the light receiving element 60 are electrically connected to electrode pads 43 and electrode pads 44 on the wiring board 40 respectively. The wiring board 40 has a through hole 41 forming an optical path LP50 for a first optical signal and a through hole 42 forming an optical path LP60 for a second optical signal.

A groove 22 is formed on the optical waveguide substrate 20. A long axis direction of the groove 22 is parallel to a long axis direction of the core 23, and has a rectangular shape in cross section orthogonal to a long axis of the groove 22. An upper surface of the groove 22 is open, and a bottom surface of the groove 22 is formed of an upper surface 25AS1 of the lower cladding 25A. Here, by bounding the wiring board 40 to an upper surface of the groove 22, the groove 22 forms a hole with one end thereof open.

Further, a first reflective surface 21M with an inclination angle of 45 degrees is formed on the core 23. The first reflective surface 21M is an inclined surface of a recessed portion 21 formed from a lower surface side by excimer laser processing, for example. The first reflective surface 21M reflects light which is incident on the core 23 from the vertical direction (Z axis direction) by 90 degrees thus guiding the light to the optical path LP23 extending in the longitudinal direction (X axis direction) of the core 23. Here, the recessed portion 21 may be a groove formed by a dicing blade.

Further, at the time of manufacture, the core 23 further extends from a vertical surface 21T of the recessed portion 21. After the recessed portion 21 is formed, however, a portion of the core 23 disposed further on the outer side than the first reflective surface 21M does not function as an optical waveguide so that the first reflective surface 21M forms an end surface of the core 23 forming the optical waveguide.

On the other hand, a prism 30 and the optical fiber 70 are disposed in the groove 22. The prism 30 is an approximately rectangular parallelepiped body having a rectangular shape as viewed in a plan view, and has a second reflective surface 30M with an inclination angle of 45 degrees. The second reflective surface 30M allows an optical signal with first wavelength to pass therethrough, but reflects an optical path of a second optical signal with second wavelength thereon. That is, the prism 30 is a right-angle dichroic prism having the reflective surface 30M with characteristics that allow light of wavelength λ1 to pass therethrough and that reflect light of wavelength λ2 thereon.

As shown in FIG. 1, the light emitting element 50 and the light receiving element 60 are mounted on the first board (wiring board) 40, and the first board 40 is disposed on the upper surface of the optical waveguide substrate 20. Further, the first board 40 and the optical waveguide substrate 20 are positioned so that the light emitting element 50 and the light receiving element 60 are right above the core 23.

The light emitting element 50 emits (transmits) a first optical signal to the optical path LP50 perpendicular to the X axis. The first optical signal is reflected on the first reflective surface 21M in the direction parallel to an X axis thus being guided to the optical path LP23. In other words, the first reflective surface 21M optically couples the optical path LP50 to the optical path LP23. The first optical signal guided through the optical path LP23 passes through the second reflective surface 30M, and is incident on the optical fiber 70.

Here, an optical waveguide is not disposed in the optical waveguide substrate 20 for the optical path LP50. This is because the optical path LP50 is an optical path extending in the thickness direction (Z direction) of the optical waveguide substrate 20, and is extremely short in length and hence, a remarkable effect cannot be acquired by forming the optical waveguide for the optical path LP50. However, the optical waveguide may be disposed in the optical waveguide substrate 20 for the optical path LP50 using the same resin as the core 23.

On the other hand, the optical fiber 70 guides a second optical signal through an optical path LP70 extending parallel to the X axis. The second optical signal is reflected on the second reflective surface 30M toward the direction perpendicular to the X axis, and is guided to the optical path LP60. Further, the second optical signal is incident on and received by the light receiving portion 61 of the light receiving element 60. In other words, the second reflective surface 30M optically couples the optical path LP60 and the optical path LP70 to each other.

In the optical-electric circuit board 1, a reflective film 26 made of a conductive material such as gold is formed on a wall surface of the recessed portion 21, particularly, on the first reflective surface 21M. In other words, the first reflective surface 21M is configured of a conductive member made of gold. Further, the reflective film 26 has a function of through wiring which electrically connects wiring 46 of the first board 40 and wiring 16 of the second board 10 with each other.

The wiring 46 is connected to the connection terminals 52 of the light emitting element 50 through the electrode pads 43. On the other hand, the wiring 16 is connected to one of two signal cables 76. That is, a drive signal supplied from one signal cable 76 is transmitted to the light emitting element 50 through the reflective film 26.

Here, after the reflective film 26 is disposed, the inside of the recessed portion 21 may be filled with a resin material or other material.

In the optical-electric circuit board 1, the reflective film 26 which is a component of an optical circuit has a function as wiring which is a component of an electric circuit. With such a configuration, in the optical-electric circuit board 1, it is not necessary to dispose a wiring board or the like having through wiring on the periphery of the optical waveguide substrate 20 and hence, it is possible to provide the miniaturized optical-electric circuit board 1. Further, the through wiring can be formed simultaneously with the formation of the optical waveguide substrate 20 and hence, the optical-electric circuit board 1 can be easily manufactured.

Here, it is sufficient for the reflective film 26 to be electrically connected with either one of the wiring 46 of the first board 40 or the wiring 16 of the second board 10. That is, it is not always necessary for the reflective film 26 to form through wiring, and it is sufficient for the reflective film 26 to have a function as wiring connected to either one of electrical wirings.

### Modification of First Embodiment

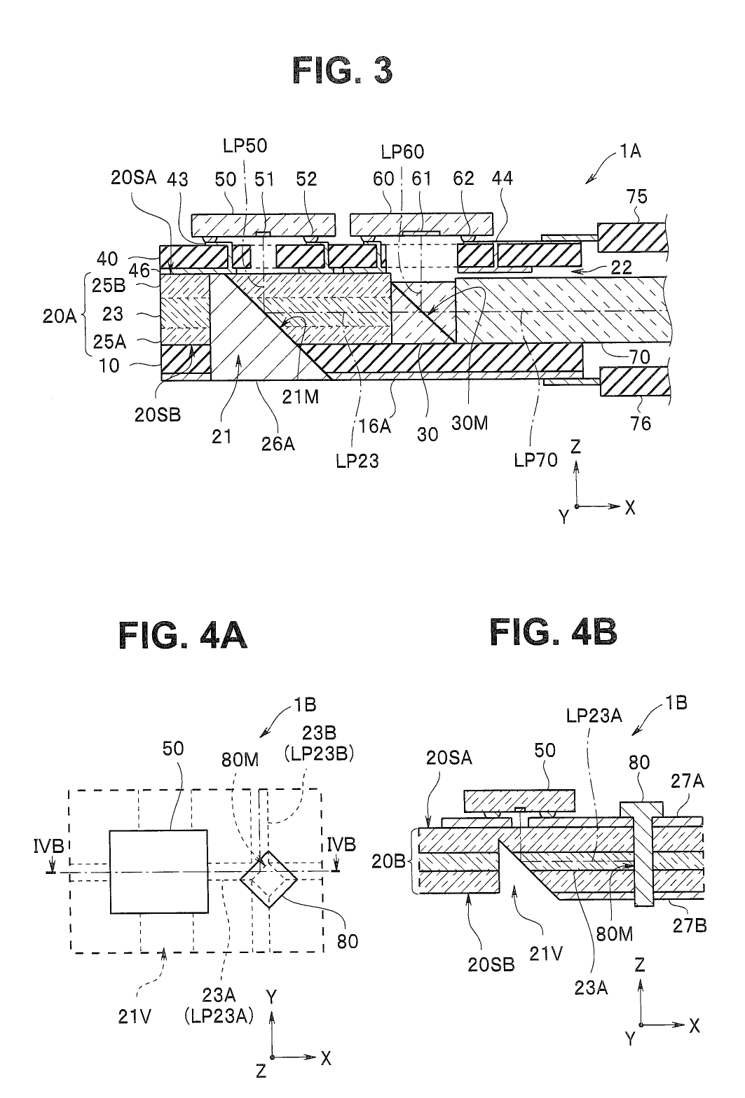

FIG. 3 shows an optical-electric circuit board 1A according to a modification of the first embodiment. The optical-electric circuit board 1A is similar to the optical-electric circuit board 1, and has substantially the same advantageous effects as the optical-electric circuit board 1. Accordingly, constitutional elements of the optical-electric circuit board 1A having substantially the same function as the corresponding constitutional elements of the optical-electric circuit board 1 are given the same symbols, and the description of such constitutional elements is omitted.

In the optical-electric circuit board 1A, the inside of the recessed portion 21 is filled with a conductive member 26A made of a silver paste, for example. In other words, the first reflective surface 21M is configured of the conductive member 26A. Further, the conductive member 26A electrically connects the wiring 46 of the first board 40 and the wiring 16 of the second board 10 with each other.

It is not necessary that the inside of the recessed portion 21 is completely filled with a conductive material with no gap. It is sufficient for the conductive material to cover at least a wall surface forming a reflective surface, a connecting portion with the wiring 46 of the first board 40 and a connecting portion with the wiring 16 of the second board 10.

As the conductive material, a conductive resin or other resin may be used in place of a conductive paste or the like made of a conductive powder and a resin.

The optical-electric circuit board 1A can be manufactured more easily than the optical-electric circuit board 1.

### Second Embodiment

FIG. 4A and FIG. 4B show an optical-electric circuit board 1B of a second embodiment. The optical-electric circuit board 1B is similar to the optical-electric circuit board 1, and has substantially the same advantageous effects as the optical-electric circuit board 1. Accordingly, constitutional elements of the optical-electric circuit board 1B having substantially the same function as the corresponding constitutional elements of the optical-electric circuit board 1 are given the same symbols, and the description of such constitutional elements is omitted.

In the optical-electric circuit board 1B, both of two optical paths LP23A, LP23B are arranged in the optical waveguide substrate 20 such that the optical paths LP23A, LP23B are orthogonal to each other in an XY plane. Further, a micro pin 80 with a side surface forming a reflective surface 80M is inserted into a guide hole (not shown in the drawing) formed in the optical waveguide substrate 20 from the upper surface 20SA.

Light generated by the light emitting element 50 is reflected on an inclined surface of a V groove 21V, and is guided to the optical path LP23A of a first waveguide 23A. The light guided through the optical path LP23A is reflected on the reflective surface 80M of the micro pin 80, and is guided to the optical path LP23B of a second waveguide 23B. That is, the reflective surface 80M optically couples the optical path LP23A and the optical path LP23B to each other.

The micro pin 80 made of a gold alloy also has a function as through wiring which electrically connects wiring 27A disposed on the upper surface 20SA of the optical waveguide substrate 20B and wiring 27B disposed on the lower surface 20SB of the optical waveguide substrate 20B with each other.

Here, the wiring 27B is a ground potential film which is electrically connected with ground potential wiring of the signal cable 76 not shown in the drawing. That is, wiring to which the micro pin 80 is connected is not limited to wiring through which an electrical signal is transmitted, and may be ground potential wiring. A ground potential film is disposed on the upper surface (first principal surface) 20SA or the lower surface (second principal surface) 20SB of the optical waveguide substrate 20B so that the optical waveguide substrate 20B has sufficiently high noise resistance.

It is also not limited that the reflective surface 80M is configured of one surface of the micro pin 80. For example, as described with reference to FIG. 1, it may be possible to adopt the configuration where a recessed portion forming a through hole is formed in a region which corresponds to an arrangement position of the micro pin 80 by dry etching such as RIE or other etching, and a metal film is formed on an inner wall of the recessed portion by electroless plating or the like thus forming the reflective surface 80M.

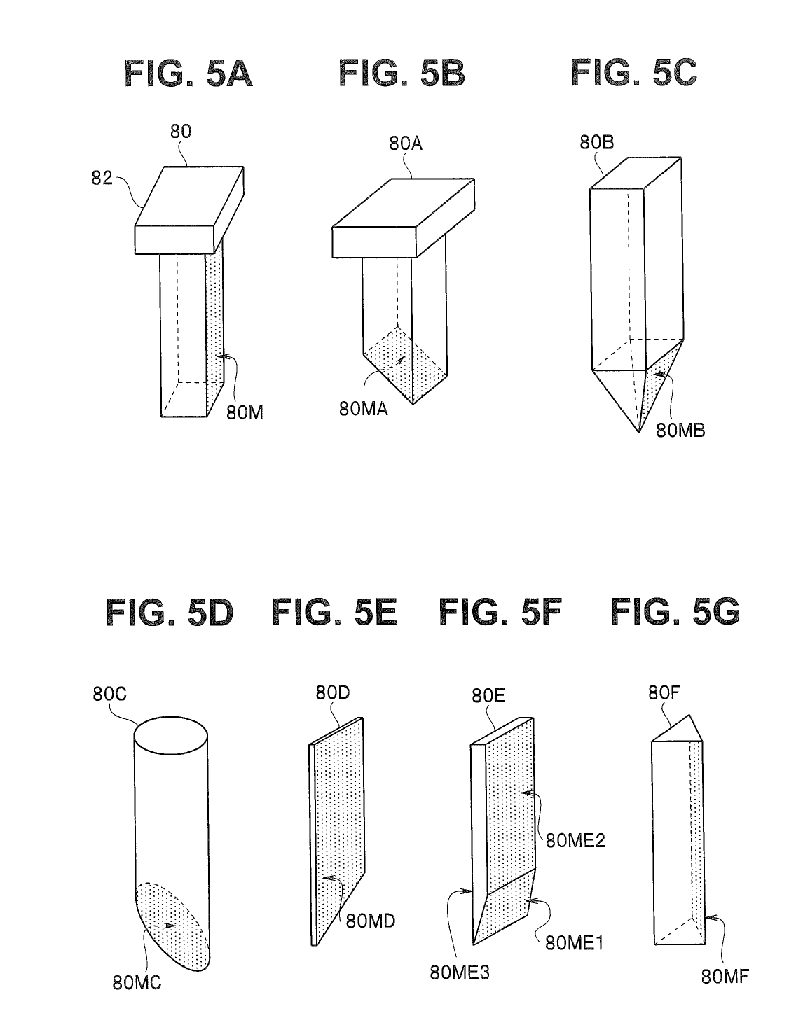

As shown in FIG. 5A, the micro pin 80 has a quadrangular prism shape, and the side surface of the micro pin 80 has a function as the reflective surface 80M. A proximal end portion of the micro pin 80 forms a holding portion 82. Here, although the holding portion 82 is not an indispensable constitutional element, the holding portion 82 is disposed so as to facilitate handling of the micro pin 80. For example, the micro pin 80 with the holding portion 82 including a ferromagnetic body can be held by a jig having a magnet thus having sufficiently high operability. The micro pin 80 and the holding portion 82 may be made of the same material so as to be configured into an inseparable integral body.

Although the micro pin 80 is preferably made of a conductor such as a metal, it is sufficient for the micro pin 80 that at least an outer surface of the micro pin 80 be made of a conductor. For example, assume a micro pin where an insulator such as glass is used as a base material, and a conductive film made of gold or the like is disposed on a surface of the micro pin. Such a micro pin may be used in the same manner as a micro pin made of a conductor.

The guide hole into which the micro pin 80 is inserted preferably has a size slightly smaller than an outer size of the micro pin 80. For example, in the case where the outer size of the micro pin 80 is L2, when a dimension L1 of the guide hole is set to a value which satisfies an expression of (L2×0.9) (L2×0.95), no space nor other materials such as an adhesive agent exist between the micro pin 80 and the optical waveguide substrate 20. In other words, a reflective surface 50M and the optical waveguide substrate 20 are brought into close contact with each other. With such a configuration, a coupling efficiency between the first optical waveguide 23A and the second optical waveguide 23B which are optically coupled to each other by the reflective surface 50M is extremely high.

Here, assume a case where a micro pin has a small cross-sectional area. For example, in the case of the micro pin 80 having a square cross section, when a side length of the micro pin 80 is 50 μm or less, in other words, when the cross-sectional area of the micro pin 80 is 250 μm² or less, the micro pin can be pierced into the optical waveguide substrate 20 without forming the guide hole in advance. In the embodiment, “pierce” means that the micro pin 80 enters the optical waveguide substrate 20 while the micro pin 80 per se forms an insertion path by cutting.

Here, also in the case where a board is bonded to at least either one of the upper surface or the lower surface of the optical waveguide substrate 20, the micro pin can be pierced into the optical waveguide substrate 20 when the board is formed of a flexible board made of a resin.

### <Micro Pins According to Modifications>

As has been described heretofore, the micro pin is not limited to the micro pin 80 described in the second embodiment. Next, micro pins according to modifications are described.

In a micro pin 80A according to the modification shown in FIG. 5B, an inclined surface with an inclination angle of 45 degrees and a vertical surface intersect with each other at a distal end of the micro pin 80A so that the distal end of the micro pin 80A is pointed. Further, the inclined surface on a side surface of the micro pin 80A forms a reflective surface 80MA.

That is, to further facilitate the piercing of the micro pin, it is preferable for the micro pin to have a pointed distal end, that is, to have an apex angle of 90 degrees or less.

In the modification, the polymer-type optical waveguide substrate 20, that is, the core 23 and the cladding 25 are made of plastic having a Vickers hardness Hv of 0.5 GP, for example. On the other hand, the micro pin 80A is made of a gold alloy having a Vickers hardness Hv of 20 GPa to piece into the optical wave guide substrate 20. To facilitate the piercing of the micro pin 80A, it is preferable that hardness of the micro pin be 10 or more times as large as hardness of the optical waveguide substrate 20.

A micro pin 80B according to a modification shown in FIG. 5C has a shape where a lower portion of the micro pin 80B has a quadrangular pyramid shape having an apex angle of 90 degrees and an upper portion of the micro pin 80B has an elongated rectangular parallelepiped shape. The micro pin 80B does not have the holding portion. In the micro pin 80B, a side surface, that is, a surface of the quadrangular pyramid body forms a reflective surface 80MB.

In the modification, in the case of a micro pin having a plurality of side surfaces such as the micro pin 80B, only any one reflective surface may be used for changing an optical path of an optical signal, or the plurality of side surfaces may optically couple respective optical paths to each other. That is, one micro pin may optically couple different optical paths to each other.

Here, in the micro pin 80B, a side surface of the upper portion having an elongated rectangular parallelepiped shape may be used as a reflective surface. Further, the surface of the quadrangular pyramid body and the side surface of the rectangular parallelepiped body may be respectively used as the reflective surface.

A micro pin 80C shown in FIG. 5D is formed such that a cutout surface formed on a lower side of a circular column body forms a reflective surface 80MC.

A micro pin 80D shown in FIG. 5E is formed of a flat plate having knife-shaped edges, and both principal surfaces of the micro pin 80D can be used as a reflective surface 80MD. A plate thickness of the micro pin 80D is set to approximately 10 μm to 500 μm.

A micro pin 80E shown in FIG. 5F has a flat plate shape where a cutout surface 80ME1 is formed on a lower side of the micro pin 80E. Not only the cutout surface 80ME1 but also an upper surface 80ME2 and a back surface 80ME3 can be used as a reflective surface.

A micro pin 80F shown in FIG. 5G has a triangular prism shape, and a side surface 80MF forms a reflective surface.

Here, the micro pin may be a flat plate body made of a transparent material, for example, glass. The reflective surface 50M may be formed of a half mirror. Further, a predetermined function may be imparted to the reflective surface by disposing a bandpass filter, a polarizing filter or the like on the reflective surface of the micro pin.

It is not necessary for the reflective surface of the micro pin to have conductivity, and it is sufficient that at least one surface of the micro pin have conductivity. For example, in the case of a micro pin made of glass, it may be configured such that one side surface of the micro pin forms the reflective surface, and three side surfaces of the micro pin are covered by a conductive film That is, it is sufficient that at least a portion of a member which configures the reflective surface be formed of a conductive member.

As has been described above, in the optical-electric circuit board of the embodiment, various micro pins may be used according to a specification. A plurality of micro pins may be pierced into one optical-electric circuit board, and may be pierced into the optical-electric circuit board not only from an upper surface but also from a lower surface or a side surface of the optical-electric circuit board. Here, in the optical-electric circuit board having the plurality of micro pins, not all micro pins are required to have a function as a conductive member.

### Third Embodiment

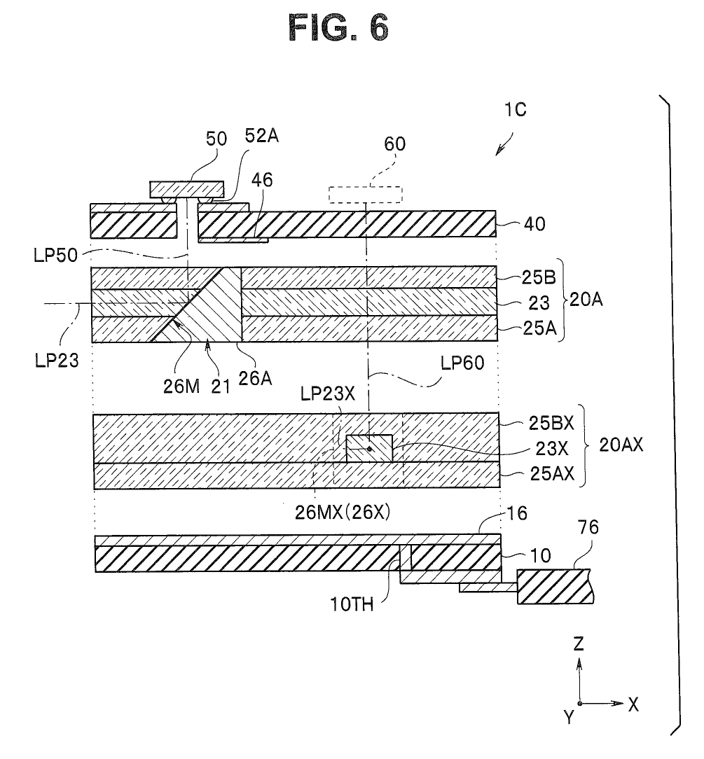

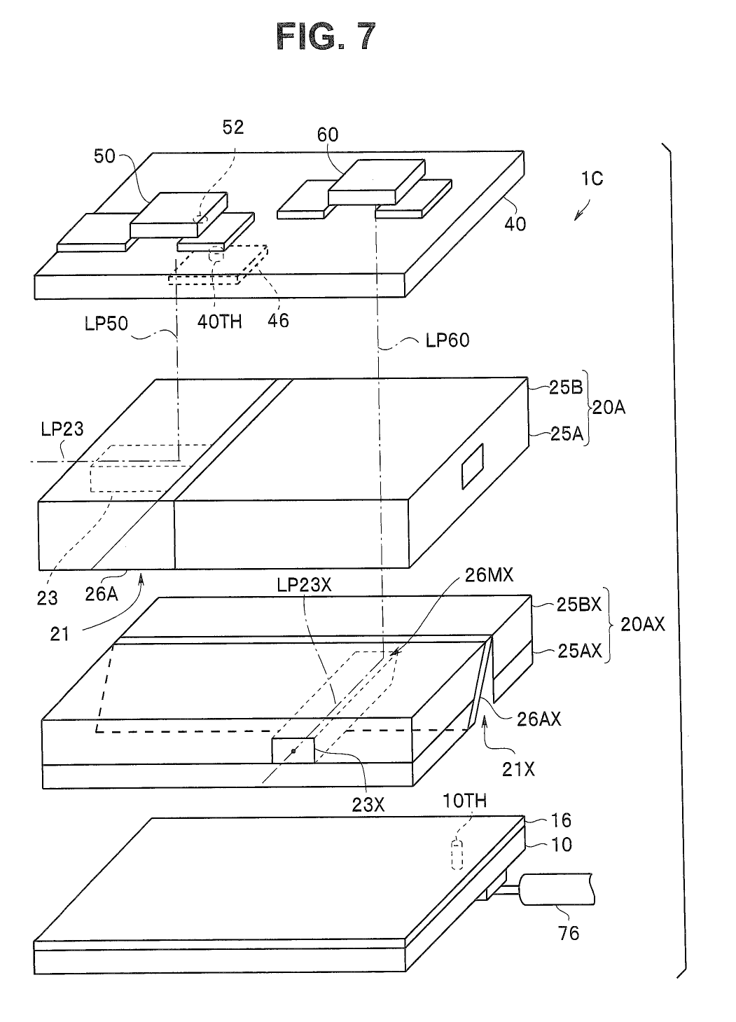

FIG. 6 and FIG. 7 show an optical-electric circuit board 1C of a third embodiment. The optical-electric circuit board 1C is similar to the optical-electric circuit board 1, and has substantially the same advantageous effects as the optical-electric circuit board 1. Accordingly, constitutional elements of the optical-electric circuit board 1C having substantially the same function as the corresponding constitutional elements of the optical-electric circuit board 1 are given the same symbols, and the description of such constitutional elements is omitted. Here, the description is made hereinafter only with respect to an electrical connection relationship between one connection terminal 52A of the light emitting element 50 and one signal cable 76.

In the optical-electric circuit board 1C, the optical waveguide substrate 20A and an optical waveguide substrate 20AX are stacked with each other. Further, the optical-electric circuit board 1C has two optical waveguides 23, 23X which are orthogonal to each other in a plane. Here, differently to the optical-electric circuit board 1 and other optical-electric circuit boards, the light emitting element 50 and the light receiving element 60 are not arranged on the same straight line.

The conductive member 26A filled in the recessed portion 21 of the optical waveguide substrate 20A configures a reflective surface 26M. A conductive member 26AX is formed on an inclined surface of a recessed portion 21X of the optical waveguide substrate 20AX, and the conductive member 26AX configures a reflective surface 26MX.

Light generated by the light emitting element 50 is reflected on the reflective surface 26M through the optical path LP50 of the optical waveguide 23, and is guided to the optical path LP23. On the other hand, light guided through an optical path LP23X of the optical waveguide 23X is reflected on the reflective surface 26MX, and is guided to the optical path LP60 and, then, is incident on the light receiving element 60.

That is, the direction of the optical path LP23 and the direction of the optical path LP23X are orthogonal to each other. Light generated by the light emitting element 50 is guided through the optical paths LP50, LP23 in the optical waveguide substrate 20A. The light receiving element 60 receives light which is guided through the optical path LP23X in the optical waveguide substrate 20AX, and is reflected on the reflective surface 26MX of the optical waveguide substrate 20AX.

The connection terminal 52A of the light emitting element 50 is electrically connected to the wiring 46 through wiring 40TH. The wiring 46 is electrically connected to the conductive member 26A which configures the reflective surface 26M of the optical waveguide substrate 20A. The conductive member 26A is electrically connected to the reflective film 26AX formed of a conductive member which configures the reflective surface 26MX of the optical waveguide substrate 20AX. The conductive member 26AX is electrically connected to the wiring 16 of the wiring board 10. The wiring 16 is electrically connected to the signal cable 76 through wiring 10TH.

That is, in the optical-electric circuit board 1C, the light emitting element 50 mounted on the second wiring board 40 is connected to the signal cable 76 through the through wiring 40TH, the wiring 46, the conductive member 26A, the reflective film 26AX, the wiring 16 and the through wiring 10TH.

As has been described above, in the optical-electric circuit board 1C, two optical waveguide substrates 20A, 20AX are stacked with each other, and each of the optical waveguide substrates 20A, 20AX has a basic configuration where a reflective surface of an optical circuit has a function as wiring of an electric circuit. That is, a more-complicated optical circuit may be configured by stacking the optical waveguide substrates with each other. Also in such a case, a reflective surface of each optical waveguide substrate is made of a conductive material and hence, it is possible to impart a function as wiring of an electric circuit to the reflective surfaces.

It is needless to say that, even in the case of an optical-electric circuit board where three or more optical waveguide substrates are stacked with each other, such an optical-electric circuit board has substantially the same advantageous effect as the optical-electric circuit board 1C.

The present invention is not limited to the above-mentioned embodiments, modifications and the like, and various changes, combinations and variations are conceivable without departing from the gist of the invention.

What is claimed is:

1. An optical-electric circuit board comprising: a polymer-type optical waveguide substrate provided with a reflective surface which optically couples a first optical path and a second optical path to each other; and electrical wiring, wherein
at least a portion of a member which configures the reflective surface is formed of a conductive member,
the electrical wiring is formed of first wiring disposed on a side of a first principal surface of the optical waveguide substrate and second wiring disposed on a side of a second principal surface of the optical waveguide substrate, and
the conductive member electrically connects the first wiring and the second wiring with each other.

2. The optical-electric circuit board according to claim 1, wherein the conductive member is a conductive film disposed on a wall surface of a recessed portion with one surface forming the reflective surface.

3. The optical-electric circuit board according to claim 1, wherein the conductive member is made of a conductor filled in a recessed portion with one surface forming the reflective surface.

4. The optical-electric circuit board according to claim 1, wherein the conductive member is a micro pin which is inserted into the optical waveguide substrate from an outer surface of the optical waveguide substrate, and has a side surface forming the reflective surface.

5. The optical-electric circuit board according to claim 4, wherein the micro pin is pierced into the optical waveguide substrate from the outer surface of the optical waveguide substrate.

6. The optical-electric circuit board according to claim 1, wherein the first wiring forms wiring of a first wiring board adhered to the first principal surface, and the second wiring forms wiring of a second wiring board adhered to the second principal surface.

7. The optical-electric circuit board according to claim 1, wherein the electrical wiring is a ground potential film disposed on a first principal surface or a second principal surface of the optical waveguide substrate.

8. An optical-electric circuit board where the optical waveguide substrate is stacked with another optical waveguide substrate, wherein the other optical waveguide substrate has a basic configuration described in claim 1.
